(19) United States
(12) Patent Application Publication
(10) Pub. No.: US 2016/0086956 A1
(43) Pub. Date: Mar. 24, 2016

(54) SEMICONDUCTOR DEVICE AND METHOD FOR MANUFACTURING SEMICONDUCTOR DEVICE

(71) Applicant: PS5 LUXCO S.a.r.l., Luxembourg (LU)

(72) Inventor: Yoichi Fukushima, Tokyo (JP)

(21) Appl. No.: 14/787,964

(22) PCT Filed: Apr. 16, 2014
(86) PCT No.: PCT/JP2014/061586

§ 371 Date: Oct. 29, 2015

(30) Foreign Application Priority Data
Apr. 30, 2013 (JP) 2013-095862

(51) Int. Cl. H01L 27/108; H01L 23/535; H01L 29/423

(52) U.S. Cl. CPC H01L 27/10823; H01L 29/4236; H01L 23/535; H01L 27/10876; H01L 27/10888; H01L 27/10885

(57) ABSTRACT

One semiconductor device has a groove formed on one surface of a semiconductor substrate, a gate electrode formed on the lower part of the groove with a gate insulation film interposed there between, a side wall insulation film made of a nitride film formed on the inner wall of the groove above the gate electrode, and an embedded insulation film formed in the groove enclosed by the side wall insulation film above the gate electrode. The side wall insulation film is shaped so that the width increases closer the bottom part of the groove.

### TECHNICAL FIELD

The present invention relates to a semiconductor device and to a method for manufacturing a semiconductor device.

### BACKGROUND

Miniaturization of semiconductor devices such as dynamic random access memories (DRAMs) has progressed in recent years. There are problems when the gate length of a transistor employed in a DRAM is reduced in that the short channel effect of the transistor becomes pronounced and there is a reduction in the threshold voltage. Furthermore, there is an increase in the junction leakage current when the impurity concentration of a semiconductor substrate is increased in order to limit a reduction in the threshold voltage of the transistor. When a DRAM memory cell is miniaturized, deterioration of the refresh characteristics is therefore a serious problem.

A trench-gate transistor in which a gate electrode is embedded in a trench formed in the surface side of a semiconductor substrate is known as a structure for avoiding problems such as those mentioned above. By using a trench-gate transistor, it is possible to ensure that the gate length of a transistor employed in a DRAM is sufficiently large in physical terms. Furthermore, it is possible to realize a DRAM having miniaturized memory cells with a minimum processing dimension of no greater than 60 nm.

However, as semiconductor devices become even smaller, a new problem has become evident in that, when contact plugs are formed in order to provide conduction between the gate electrodes of a trench-gate transistor and a capacitor or upper electrode etc., short circuiting is likely to occur between the gate electrodes and the contact plugs as a result of part of an embedded insulating film formed beforehand in the trench being excessively etched.

Various semiconductor devices and methods for manufacturing said semiconductor devices are being investigated in order to solve new problems such as that mentioned above. For example, Patent Document 1 describes a semiconductor device and a method for manufacturing a semiconductor device, the method comprising the following steps: a step in which an embedded insulating film comprising borophosphosilicate glass is formed on a gate electrode (buried word line) within a gate electrode-formation trench (referred to below simply as a “trench”); a step in which an interlayer insulating film is formed on the embedded insulating film and a semiconductor substrate; and a step in which a contact opening reaching the embedded insulating film and the surface of the adjacent semiconductor substrate is formed in the interlayer insulating film by means of etching.

Specifically, as shown in FIG. 9-FIG. 11 of Patent Document 1, an embedded insulating film 72 comprising borophosphosilicate glass (BPSG) is deposited by means of CVD on a liner film 71 formed in a trench groove 65. After this, a silicon nitride mask film and part of the embedded insulating film 72 and liner film 71 are removed by means of an etching and planarization step employing CMP, and the embedded insulating film 72 is formed in such a way that the surface thereof is at a comparable height with the silicon surface of a semiconductor substrate 50. Patent Document 1 indicates that the boron (B) concentration of the BPSG is preferably in the range of 10.5-11.0 mol %, and the ratio of the boron (B) concentration and the phosphorus (P) concentration is preferably 2.34-2.76, from the point of view of improving etching resistance.

### PATENT DOCUMENTS

### Patent Document 1: JP 2011-129760 A

### SUMMARY OF THE INVENTION

### Problem to be Solved by the Invention

During the manufacture of a semiconductor device such as a DRAM having a trench-gate transistor, the embedded insulating film is formed on the gate electrode, after which a capacitance contact opening is formed using photolithography and dry etching in such a way as to adjoin the embedded insulating film and the semiconductor substrate. Here, the capacitance contact opening and the surrounding area are washed by means of wet etching employing a chemical solution such as hydrofluoric acid. The BPSG described in Patent Document 1 has a certain degree of resistance to wet etching, but it may be considerably removed during the abovementioned washing process. When the embedded insulating film on the gate electrode is removed, the gate electrode short circuits with a capacitance contact plug which is subsequently formed. Although it is possible to reduce the thickness of the gate electrode with respect to the thickness of the trench in order to maintain a margin of insulation in the gate electrode, this leads to the problem of an increase in the electrical resistance of the gate electrode.

In this regard, it was thought feasible to reliably avoid short circuiting between the gate electrode and the capacitance contact plug by employing, as the embedded insulating film, an insulating film formed by means of a high-density plasma (HDP) method, which has excellent properties such as high resistance to hydrofluoric acid etching. When an insulating film formed by means of an HDP method is used however, the edge portions at the upper end of the gate electrode-formation trench (referred to below simply as the “trench”) which has a high aspect ratio are removed by the sputtering effect. There is thus a problem in that it is impossible to ensure an adequate margin of insulation in the gate electrode, due to the fact that the insulating film cannot be readily embedded in the trench.

### Means for Solving the Problem

A semiconductor device according to the present invention comprises: a trench formed in one surface of a semiconductor substrate; a gate electrode formed in a lower part of the trench with a gate insulating film interposed; a side wall insulating film comprising a nitride film formed on an inner wall of the trench on the gate electrode; and an embedded insulating film which is formed within the trench enclosed by the side wall insulating film on the gate electrode, wherein the side wall insulating film has a shape which increases in width toward a bottom part of the trench.

A method for manufacturing a semiconductor device according to the present invention comprises the following steps: a trench formation step in which a trench is formed in one surface of a semiconductor substrate; a gate insulating film formation step in which a gate insulating film is formed at a lower part of an inner wall of the trench; a gate electrode formation step in which a gate electrode is formed at a lower part of the trench with the gate insulating film interposed; a side wall insulating film formation step in which a side wall insulating film comprising a nitride film which increases in width toward a bottom part of the trench is formed on an inner wall of the trench on the buried word line; and an embedded insulating film formation step in which an embedded insulating film is formed within the trench enclosed by the side wall insulating film on the gate electrode.

### Advantage of the Invention

According to the present invention, the interior angle formed by one surface of a semiconductor substrate at an upper end of a trench and an inner wall of a side wall insulating film is an obtuse angle, so a mortar-shaped space is formed within the trench on the gate electrode. As a result, it is possible to use, as an embedded insulating film, an insulating film which has outstanding etching characteristics even though it cannot be readily embedded in the trench, and said film may be embedded in the space inside the trench on the gate electrode. The etching resistance of the embedded insulating film is therefore improved, and there is no removal of the embedded insulating film when contact plugs and wiring adjoining the embedded insulating film and semiconductor substrate are formed, even if wet etching or chemical washing etc. is performed, so it is possible to maintain the insulating properties of the gate electrodes while also being able to reliably avoid short circuiting of the contact plugs or wiring.

### BRIEF DESCRIPTION OF THE FIGURES

FIG. 1 is a plan view showing the configuration of a semiconductor device according to a first mode of embodiment of the present invention;

FIG. 2 is a view in cross section showing the configuration of the main parts of the semiconductor device according to the first mode of embodiment of the present invention, illustrating a cross section along the line A-A′ shown in FIG. 1;

FIG. 3 is a view in cross section showing a step in the manufacture of the semiconductor device according to the first mode of embodiment of the present invention;

FIG. 4 is a view in cross section showing a step in the manufacture of the semiconductor device according to the first mode of embodiment of the present invention;

FIG. 5 is a view in cross section showing a step in the manufacture of the semiconductor device according to the first mode of embodiment of the present invention;

FIG. 6 is a view in cross section showing a step in the manufacture of the semiconductor device according to the first mode of embodiment of the present invention;

FIG. 7 is a view in cross section showing a step in the manufacture of the semiconductor device according to the first mode of embodiment of the present invention;

FIG. 8 is a view in cross section showing a step in the manufacture of the semiconductor device according to the first mode of embodiment of the present invention;

FIG. 9 is a view in cross section showing a step in the manufacture of the semiconductor device according to the first mode of embodiment of the present invention;

FIG. 10 is a view in cross section showing a step in the manufacture of the semiconductor device according to the first mode of embodiment of the present invention;

FIG. 11 is a view in cross section showing a step in the manufacture of the semiconductor device according to the first mode of embodiment of the present invention;

FIG. 12 is a view in cross section showing a step in the manufacture of the semiconductor device according to the first mode of embodiment of the present invention;

FIG. 13 is a view in cross section showing a step in the manufacture of the semiconductor device according to the first mode of embodiment of the present invention;

FIG. 14 is a view in cross section showing a step in the manufacture of the semiconductor device according to the first mode of embodiment of the present invention;

FIG. 15 is a view in cross section showing a step in the manufacture of the semiconductor device according to the first mode of embodiment of the present invention;

FIG. 16 is a view in cross section showing a step in the manufacture of the semiconductor device according to the first mode of embodiment of the present invention;

FIG. 17 is a view in cross section showing a step in the manufacture of a semiconductor device according to a second mode of embodiment of the present invention;

FIG. 18 is a view in cross section showing a step in the manufacture of the semiconductor device according to the second mode of embodiment of the present invention; and

FIG. 19 is a view in cross section showing a step in the manufacture of the semiconductor device according to the second mode of embodiment of the present invention.

### MODE OF EMBODIMENT OF THE INVENTION

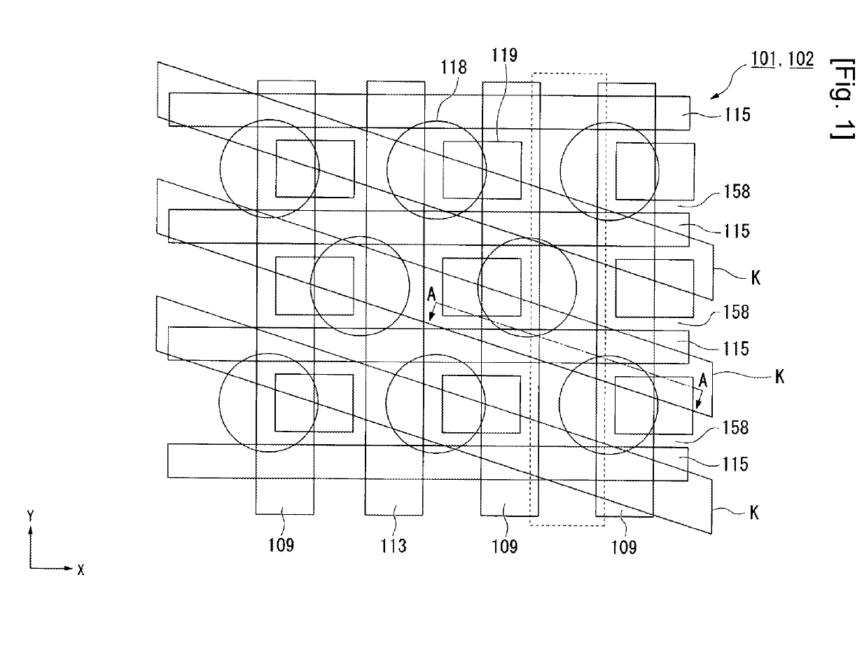

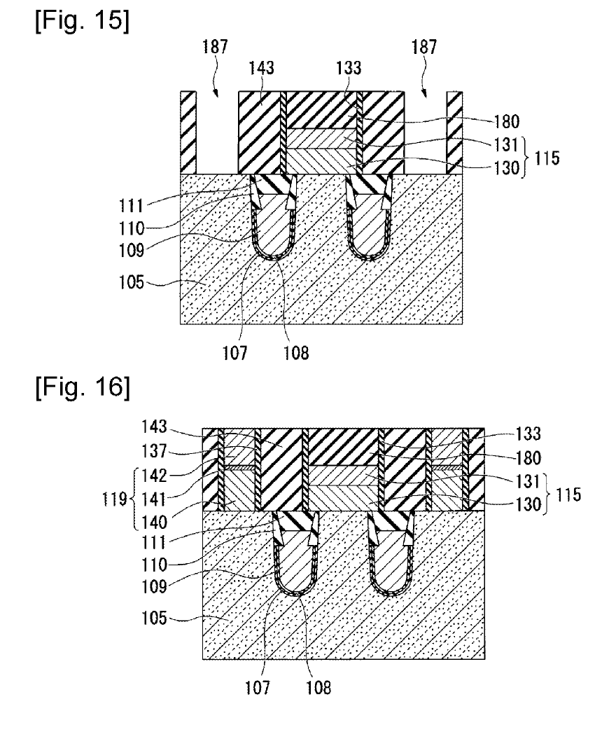

A method for manufacturing a semiconductor in accordance with the present invention will be described in detail below with reference to FIG. 1-FIG. 16. Furthermore, in FIG. 1-FIG. 16, constituent elements which are the same bear the same reference symbols and will not be described again. It should be noted that the drawings used in the following description are schematic drawings and the length, width and thickness ratios etc. are not necessarily the same as the actual dimensions.

### First Mode of Embodiment

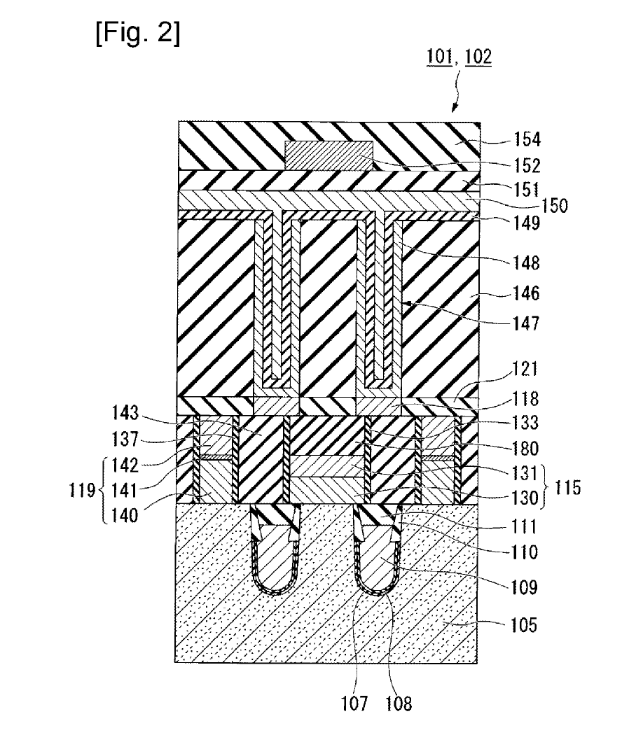

The DRAM (semiconductor device) 101 shown in FIG. 1 and FIG. 2 will be described as an example of a semiconductor device according to the first mode of embodiment.

The DRAM 101 is provided with a plurality of memory cell arrays. In FIG. 1, the Y-direction indicates the direction of extension of gate electrodes 109, and the X-direction indicates the direction of extension of bit lines 115. Furthermore, a semiconductor substrate 105 is divided into a plurality of active regions K by means of element isolation regions 113, 158. The active regions K form a parallelogram shape when seen in plan view, extending in a direction which is inclined at a given angle with respect to the X-direction. However, the active regions K are not limited to a parallelogram shape and a long elliptical shape or another planar shape is equally feasible.

It should be noted that FIG. 1 illustrates only the element isolation regions 113, 158, the active regions K, the gate electrodes 109, the bit lines 115, capacitance contact pads 118 and capacitance contact plugs (contact plugs) 119 from among the constituent elements of the memory cell array, and other constituent elements of the memory cell array are omitted from the drawings for the sake of convenience.

As shown in FIG. 2, two trench-gate transistors are provided in each active region K, and a capacitor 147 and upper metal wiring 152 are provided on each trench-gate transistor; the memory cell array is constructed by means of these structures. The trench-gate transistors in each active region K have a double-gate structure comprising individual gate electrodes 109 and a shared bit line 115, but the structure is not limited to this form. The two adjacent trench-gate transistors comprise a gate insulating film 107, an inner surface layer 108, the gate electrode 109, a side wall insulating film 110 and an embedded insulating film 111, and share the semiconductor substrate 105 in the center of the active region K.

The gate insulating film 107 is formed in such a way as to cover a lower part of an inner wall of two trenches 106 provided in each active region K. The inner surface layer 108 is formed on the inside of the gate insulating film 107. A silicon dioxide film and a titanium nitride film may be used as the gate insulating film 107 and the inner surface layer 108, respectively, for example.

The gate electrode 109 functions as a word line in the trench-gate transistor and is formed by an upper portion 109B and a lower portion 109A. The lower portion 109A is formed in such a way as to fill the inside of the trench 106 enclosed by the gate insulating film 107 and the inner surface layer 108. The upper portion 109B is formed in such a way as to fill the inside of the trench 106 enclosed at a lower part of a side wall insulating film 110 to be described later. Tungsten may be used as the material of the upper portion 109B and the lower portion 109A, for example. The height of the gate electrode 109 is set in accordance with the refresh characteristics of the DRAM 101 and the height of the trench 106, among other things.

The side wall insulating film 110 is formed above the gate electrode 109 in such a way as to cover an upper part of the inner wall of the trench 106. A nitride film formed by means of atomic layer deposition (ALD) may be used as the material of the side wall insulating film 110 of the DRAM 101. Furthermore, the side wall insulating film 110 increases in width toward a bottom part of the trench 106 and has a quasi-tapered shape. The quasi-tapered shape of the side wall insulating film 110 is set to take account of the refresh characteristics of the DRAM 101 and the width of the trench 106, among other things.

A lower part of the side wall insulating film 110 is interposed between the upper portion 109B of the gate electrode 109 and the semiconductor substrate 105. By virtue of this arrangement, the depth of the gate electrode 109 can be adequately maintained and insulating properties are ensured, while an increase in the electrical resistance of the gate electrode 109 is also suppressed. It should be noted that the electrical resistance of the gate electrode 109 may be reduced if the lower portion 109A is sufficiently deep. In this case, the gate electrode 109 may comprise only the lower portion 109A.

The embedded insulating film 111 is formed above the gate electrode 109 in a mortar-shaped internal space of the trench 106 enclosed by the upper part of the side wall insulating film 110. A silicon dioxide film which is formed using an HDP method may be used as the embedded insulating film 111. A silicon dioxide film formed by means of an HDP method has extremely good resistance to wet etching which is used in the process of manufacturing the DRAM 101, such as removal of a silicon nitride mask film which is formed beforehand on the semiconductor substrate 105, formation of contact plugs or wiring, and surface washing. The embedded insulating film 111 of the DRAM 101 therefore has higher resistance to wet etching than a conventional film.

The semiconductor substrate 105 lying between the two gate electrodes 109, i.e. the central part of the active region K, forms a source/drain region of the trench-gate transistor, and the bit line 115 is connected thereto. Meanwhile, the semiconductor substrate 105 on the opposite side to the side on which the bit line 115 is connected with respect to the gate electrode 109 forms a source/drain region of the trench-gate transistor, the capacitance contact plug 119 is connected thereto, and the capacitor 147 is connected thereabove. An impurity diffusion region is preferably provided in the semiconductor substrate 105 where the source/drain regions of the trench-gate transistor are formed. When a p-type silicon substrate is used as the semiconductor substrate 105, the impurity diffusion region is formed by means of ion implantation of an n-type impurity dopant such as arsenic or phosphorus, for example.

The bit line 115 adjoins a surface 105a of the semiconductor substrate 105 and the upper surface of the embedded insulating film 111, and is formed in such a way as to extend in the X-direction. The bit line 115 has a two-layer structure comprising a bottom conductive film 130 made of polysilicon and a metallic film 131 made of a high-boiling-point metal such as tungsten, for example, but this is not limiting. An upper insulating film 32 such as a silicon nitride film is formed on the bit line 115. An insulating film 133 comprising a silicon nitride film or the like is formed on both sides in the width direction of the bit line 115. It should be noted that a bit line contact plug may be disposed between the bit line 115 and the semiconductor substrate 105.

The capacitance contact plug 119, which has a rectangular shape in plan view, adjoins the surface 105a of the semiconductor substrate 105 which is not in contact with the bit line 115, and adjoins the upper surface of the embedded insulating film 111. The capacitance contact plug 119 has a three-layer structure comprising a bottom conductive film 140 made of polysilicon or the like, a silicide layer 141 comprising CoSi or the like, and a metallic film 142 such as tungsten, for example, but this is not limiting. An insulating film 137 comprising a silicon nitride film or the like is formed on both sides in the width direction of the capacitance contact plug 119.

An interlayer insulating film 143 comprising a silicon dioxide film or the like is formed between the bit line 115 and the capacitance contact plug 119. The upper surfaces of the bit line 115, capacitance contact plug 119 and interlayer insulating film 143 are formed in such a way as to lie at the same height. The upper part of the bit line 115 and the capacitance contact plug 119 constitutes a capacitor formation region of the DRAM 101, and capacitance contact pads 118 having a circular shape in plan view are formed in a staggered manner on the capacitance contact plugs 119 in such a way as to be partially overlapping. A stopper film 121 is formed on both sides in the width direction of each capacitance contact pad 118. An interlayer insulating film 146 comprising a silicon dioxide film or the like is formed on the stopper film 121. The capacitor 147 is formed within the interlayer insulating film 146 in such a way as to be positioned above the capacitance contact pad 118.

The capacitor 147 comprises a lower electrode 148, a capacitance insulating film 149 and an upper electrode 150. The lower electrode 148 is a cylindrical electrode portion formed on the capacitance contact pad 118. The capacitance insulating film 149 is formed in such a way as to extend from the inner surface of the lower electrode 148 over the interlayer insulating film 146. The upper electrode 150 is formed in such a way as to fill the inside of the lower electrode 148 while also extending to the upper surface of the capacitance insulating film 149. It should be noted that the structure of the capacitor 147 described is merely an example and there is no particular limitation; another capacitor structure which is conventionally used in a semiconductor device, such as a crown shape, may equally be employed.

An interlayer insulating film 151 comprising a silicon dioxide film or the like is provided on the upper electrode 150. Furthermore, upper metal wiring 152 comprising aluminum or copper, and an interlayer insulating film 154 comprising a silicon dioxide film or the like are provided on the interlayer insulating film 151.

It should be noted that a peripheral circuit region (not depicted) may be disposed around the memory cell array described above of the DRAM 101.

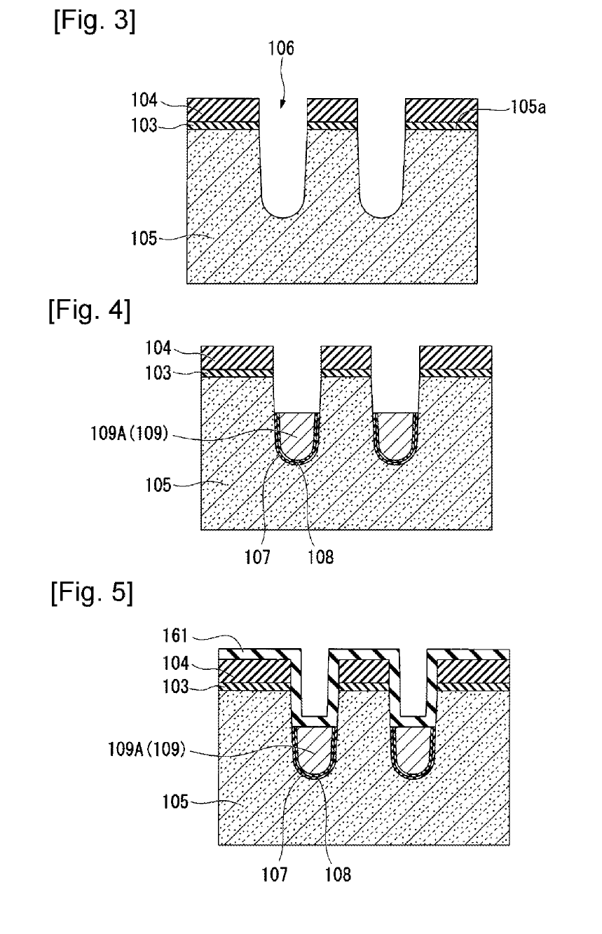

A method for manufacturing the DRAM 101 will be described next with reference to FIG. 3-FIG. 16. It should be noted that there is no particular limitation as to the materials in the following description, and these may be varied within a scope that does not depart from the essential point of the present invention. Furthermore, there is no particular limitation as to the numerical values such as film thickness in the following description; the numerical values given illustrate relative relationships and are preferably set, as appropriate, to take account of the materials and shape of the constituent elements.

A semiconductor substrate 105 comprising a p-type silicon substrate is first of all prepared, and a silicon dioxide film 103 and a silicon nitride mask film 104 are stacked in succession on a surface 105a of the semiconductor substrate 105. It should be noted that the semiconductor substrate 105 which is used may be a semiconductor substrate in which P-type wells are provided beforehand by means of ion implantation in a region in which a trench-gate transistor is formed.

The silicon dioxide film 103, silicon nitride film 104 and semiconductor substrate 105 are then patterned using photolithography and dry etching, and element isolation trenches (not depicted) for defining active regions K are formed in the surface 105a of the semiconductor substrate 105. As shown in FIG. 1, the pattern of the element isolation trenches in plan view is a linear pattern extending in a direction which is inclined at a given angle with respect to the Y-direction in such a way as to lie either side of the strip-like active regions K. After this, element isolation regions 158 having an STI structure are formed by filling the element isolation trenches with a silicon dioxide film. It should be noted that a silicon nitride film may be formed on an inner wall of the element isolation trenches, as required, and the upper surface of the element isolation regions 158 may be at a slightly lower level than the surface 105a of the semiconductor substrate 105.

Element isolation regions 113 for isolating the strip-like active regions K in a direction parallel to gate electrodes 109, i.e. the Y-direction, are formed by means of the same process, as shown in FIG. 1. It should be noted that the element isolation regions 113, 158 may be formed all together.

After this, a low-concentration n-type impurity dopant such as arsenic or phosphorus is preferably ion-implanted in the surface 105a of the semiconductor substrate 105 in the active regions K, and a low-concentration impurity diffusion layer (not depicted) functioning as a source/drain region of the trench-gate transistor is preferably formed. It should be noted that the step in which the low-concentration impurity diffusion layer is formed may be omitted.

### [Trench Formation Step]

The silicon dioxide film 103, silicon nitride film 104 and semiconductor substrate 105 are then etched using photolithography and dry etching in order to form trenches 106 for forming buried gate electrodes, as shown in FIG. 3. As shown in FIG. 1, the trenches 106 are formed as a linear pattern extending in the Y-direction intersecting the active regions K. Moreover, forming the trenches 106 in this kind of linear pattern facilitates formation of trench-gate transistors in which adjacent gate electrodes 109 share the same bit line, but there is no particular limitation as to the planar pattern of the trenches 106.

### [Gate Insulating Film Formation Step]

A gate insulating film 107 comprising a silicon dioxide film or the like is then formed on an inner wall of the trench 106 using thermal oxidation. After this, an inner surface layer 108 comprising titanium nitride is formed on the inside of the gate insulating film 107 and a tungsten layer (not depicted) is embedded. The thickness of the gate insulating film 107 and the inner surface layer 108 may be set at 5 nm in both cases, for example.

### [Gate Electrode Formation First Step]

The tungsten layer which is not depicted, the inner surface layer 108 and the gate insulating film 107 are then etched so as to remain in the lower part of the trench 106. A lower portion 109A of a gate electrode 109 comprising tungsten is formed as a result, as shown in FIG. 4.

### [Side Wall Insulating Film Formation Step]

A liner film 161 comprising a silicon nitride film or the like is then formed over the lower portion 109A in such a way as to cover an exposed upper part of the inner wall of the trench 106, as shown in FIG. 5. The material forming the liner film 161 is preferably a silicon nitride film which is formed by ALD and has a relatively slow etching rate during wet etching (referred to below as the “ALD nitride film”). The use of the ALD nitride film facilitates processing to a quasi-tapered shape.

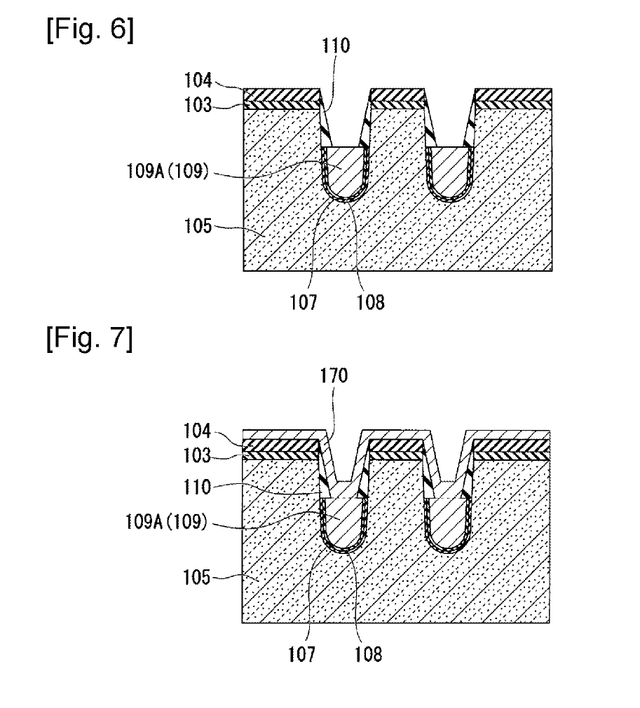

As shown in FIG. 6, the liner film 161 is then etched back using wet etching in such a way that the width thereof increases toward a bottom part of the trench 106, and a side wall insulating film 110 is formed. When the etching-back has been completed, the silicon nitride film 104 is exposed on a surface 105a of the semiconductor substrate 105 in which the trench 106 is not formed.

### [Gate Electrode Formation Second Step]

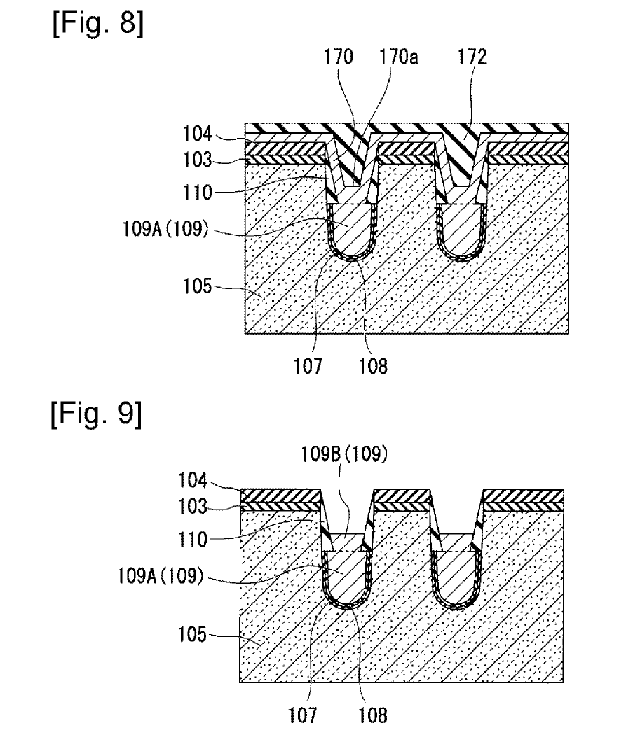

As shown in FIG. 7, a tungsten layer 170 is then formed by means of CVD in such a way as to cover the exposed silicon nitride film 104, the side wall insulating film 110 and the lower portion 109A of the gate electrode 109. The thickness of the tungsten layer 170 may be set at 15 nm, for example. As shown in FIG. 8, an antireflection film (bottom anti-reflective coating (BARC)) 172 is then applied in such a way as to cover the tungsten layer 170 and to fill the trench 106.

An upper part of the antireflection film 172 and the tungsten layer 170 is then etched back until a bottom part upper surface 170a of the tungsten layer 170 in the trench 106 is exposed. As a result, the gate electrode 109 is formed by joining of the lower portion 109A which is enclosed by the laminated film comprising the gate insulating film 107 and the inner surface layer 108, except on the upper surface thereof, and an upper portion 109B which is enclosed at the side surface by a bottom part of the side wall insulating film 110, as shown in FIG. 9. The thickness of the upper portion 109B is preferably set in accordance with the thickness of the lower portion 109A and takes account of the overall thickness of the gate electrode 109.

### [Embedded Insulating Film Formation Step]

A mortar-shaped internal space in the trench 106 enclosed by a portion above the bottom part of the side wall insulating film 110 is then filled with a silicon dioxide film (not depicted) using an HDP method. After this, the upper surface of the silicon dioxide film is planarized to form an embedded insulating film 111, as shown in FIG. 10. It should be noted that the height of the upper surface of the embedded insulating film 111 can be aligned with the height of the surface 105a of the semiconductor substrate 105 using etch-back or the like.

The silicon nitride film 104 is then removed using wet etching to expose the upper surface of the silicon dioxide film 103, as shown in FIG. 11. The side wall insulating film 110 has a slower etching rate in terms of wet etching than the gate electrode 109, so it is possible to avoid removal of the side wall insulating film 110 by etching. Furthermore, the embedded insulating film 111 comprising a silicon dioxide film is formed at the upper part of the trench 106 by means of an HDP method, so the insulating properties of the gate electrode 109 are reliably maintained.

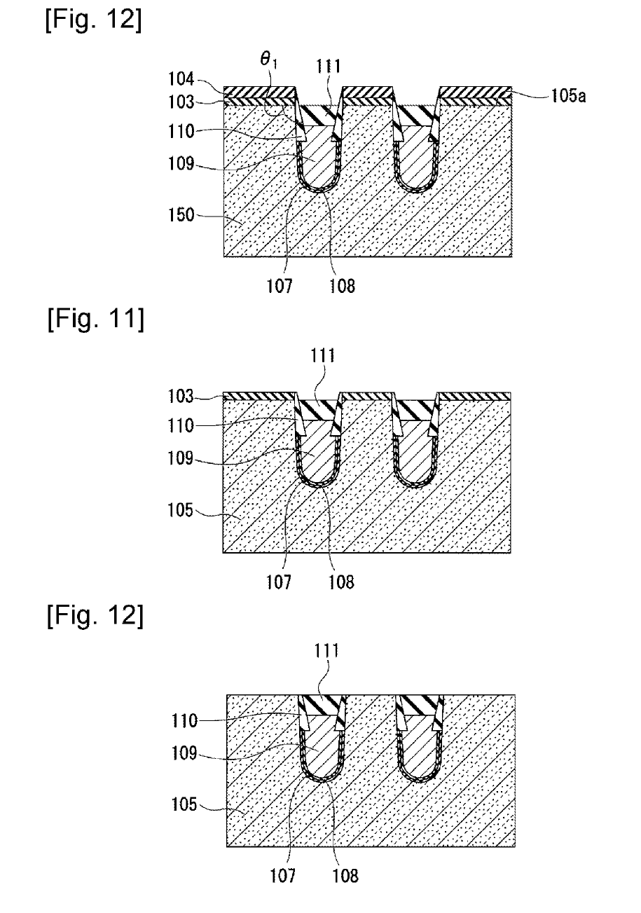

The upper part of the side wall insulating film 110 and the silicon dioxide film 103 are then removed by means of CMP, as shown in FIG. 12, and the upper surface of the embedded insulating film 111 is exposed. The gate electrode 109 functioning as a word line in the DRAM 101, and the side wall insulating film 110 and embedded insulating film 111 on the gate electrode 109 are formed by means of the above steps.

### [Bit Line Formation Step]

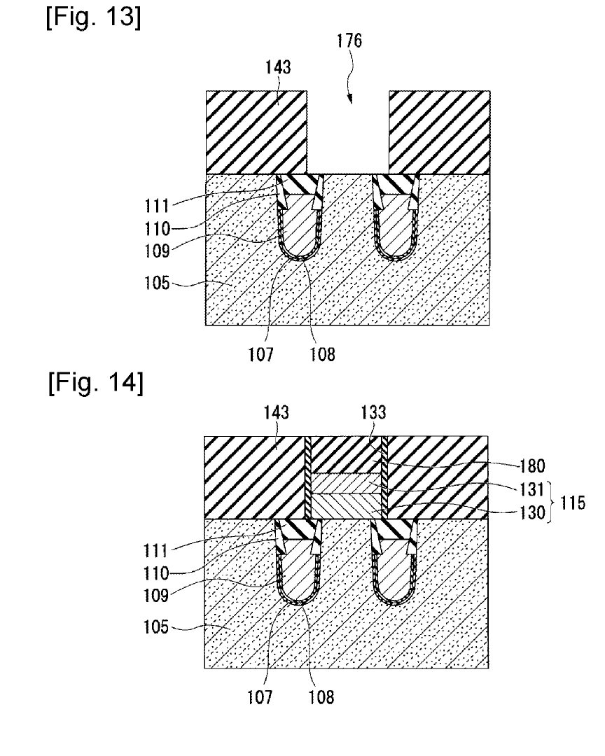

An interlayer insulating film 143 is then formed from a silicon dioxide film or the like in such a way as to cover the semiconductor substrate 105. It should be noted that the interlayer insulating film 143 may be a composite film formed by stacking a plurality of materials. After this, part of the interlayer insulating film 143 is removed by means of photolithography and dry etching, as shown in FIG. 13, and a bit line opening 176 is formed. The bit line opening 176 is formed as a linear open pattern extending in the same direction as the gate electrodes 109, i.e. the Y-direction in FIG. 1.

An insulating film 133 is then formed from a silicon nitride film on an inner wall of the bit line opening 176. After this, n-type impurity dopant may be ion-implanted in the surface 105a of the semiconductor substrate 105 exposed at a bottom surface of the bit line opening 176, and a high-concentration impurity diffusion layer (not depicted) may be formed in the region of the surface 105a of the semiconductor substrate 105.

A laminated film comprising a bottom conductive film 130 made of polysilicon or the like and a metallic film 131 made of a high-boiling-point metal such as tungsten is then embedded inside the bit line opening 176 to form a bit line 115. The bit line 115 is formed in a pattern extending in a direction intersecting the gate electrodes 109, i.e. the X-direction shown in FIG. 1. The bottom conductive film 130 which is a lower layer of the bit line 115, and the semiconductor substrate 105 forming a source/drain region are connected as a result. It should be noted that FIG. 1 shows an example of linear bit lines 115 orthogonal to the gate electrodes 109, but the bit lines 115 may equally be arranged in waveform or as broken lines which are bent in parts. After this, a silicon nitride film 180 is formed as a protective insulating film on the bit line 115, as shown in FIG. 14.

### [Contact Plug Formation Step and Capacitor Formation Step]

Part of the interlayer insulating film 143 is then removed using photolithography and dry etching, and capacitance contact openings 187 are formed. The positions in which the capacitance contact openings 187 are formed is set in such a way as to be adjacent to each trench 106 and adjoining the surface 105a of the semiconductor substrate 105 on the side not in contact with the bit line 115. That is to say, positions corresponding to capacitance contact plug formation regions 117 in the case of the structure previously described in relation to FIG. 1.

An insulating film 137 comprising a silicon nitride film is then formed on an inner wall of the capacitance contact opening 187. After this, the surface 105a of the semiconductor substrate 105 exposed on a bottom surface of the capacitance contact opening 187 may be subjected to ion implantation in order to form an n-type impurity high-concentration diffusion layer (not depicted) in the region of the surface 105a of the semiconductor substrate 105.

A phosphorus-containing polysilicon film is then deposited in the capacitance contact opening 187, after which etch-back is performed and the polysilicon film is allowed to remain at the bottom part of the capacitance contact opening 187 in order to form a bottom conductive film 140. After this, a silicide layer 141 such as cobalt silicide (CoSi) is formed on the surface of the bottom conductive film 140, and a metallic film 142 such as tungsten is deposited in such a way as to fill the capacitance contact opening 187. Surface planarization is performed by means of CMP until the surfaces of the silicon nitride film 180 and the interlayer insulating film 143 are exposed, and the metallic film 142 is left only inside the capacitance contact opening 187. A capacitance contact plug 119 having a three-layer structure comprising the bottom conductive film 140, silicide layer 141, and metallic film 142 is formed in this way, as shown in FIG. 16.

After this, capacitance contact pads 118 and a stopper film 121 are formed on the structure shown in FIG. 16 using means which are well known in conventional methods for manufacturing a DRAM. The positions in which the capacitance contact pads 118 are formed at least partly abut the upper surface of the capacitance contact plugs 119, as shown in FIG. 1.

A capacitor 147, interlayer insulating films 146, 151, 154, and upper metal wiring 152 are then formed on the capacitance contact pads 118 and stopper film 121 using means which are well known in conventional methods for manufacturing a DRAM. It should be noted that there is no particular limitation as to the type or shape of the capacitor 147.

The DRAM 101 is completed by means of the steps described above.

The DRAM 101 according to this mode of embodiment has a shape in which the width of the side wall insulating film 110 increases toward the bottom of the trench, i.e. a quasi-tapered shape, so the interior angle θ₁ formed by the surface 105a of the semiconductor substrate 105 in the region of the upper end of the trench 106 and the inner wall of the side wall insulating film 110 is an obtuse angle, and a mortar-shaped space is formed within the trench 106 on the gate electrode 109. As a result, it is possible to improve the ease with which the embedded insulating film formed on the gate electrode is embedded in said space. Accordingly, it is possible to use, as an embedded insulating film, an insulating film which has outstanding etching resistance even though it cannot be readily embedded due to the sputtering effect etc., such as a silicon nitride film employing an HDP method. Furthermore, it is possible to reliably maintain the insulating properties of the gate electrodes 109 while also being able to avoid short circuiting between the gate electrodes 109 and the capacitance contact plugs 119 or the bit lines 115. In addition, a field limiting effect is produced in the DRAM 101 by means of the side wall insulating film 110, and the refresh characteristics are improved.

Furthermore, by virtue of the method for manufacturing the DRAM 101 according to this mode of embodiment, a mortar-shaped space enclosed by the side wall insulating film 110 is formed inside the trench 106 on the gate electrode 109, as described above. As a result, it is possible to use an HDP method in order to embed the embedded insulating film 111, which has excellent etching resistance, inside the trench 106 on the gate electrode 109, without removing the upper end of the trench 106 due to the sputtering effect. This means that it is possible to form the bit line opening 176 and capacitance contact openings 187 by means of wet etching or treatment using a chemical solution or the like, without removing the embedded insulating film 111 when the bit lines 115 and the capacitance contact plug 119 are formed after the embedded insulating film 111 has been formed. It is thus possible to manufacture a DRAM 101 which reliably maintains the insulating properties of the gate electrodes and demonstrates the abovementioned advantages.

In addition, with the DRAM 101 and the method for manufacturing same according to this mode of embodiment, the etching removal resistance of the embedded insulating film 111 is improved, and as a result the upper portion 109B of the gate electrode 109 can extend inside the trench 106 enclosed by the bottom part of the side wall insulating film 110. That is to say, it is possible to increase the thickness of the gate electrode 109 while maintaining the insulating properties of the gate electrode 109. This makes it possible to reduce the electrical resistance without increasing the word line capacitance of the DRAM 101.

### Second Mode of Embodiment

A DRAM (semiconductor device) 201 will be described as an example of a semiconductor device according to the second mode of embodiment.

The structure of the DRAM 201 according to the second mode of embodiment is the same as that of the DRAM 101 according to the first mode of embodiment. A description of the structure of the DRAM 201 will therefore not be given.

The difference between this mode of embodiment and the DRAM according to the first mode of embodiment lies in the process for forming the upper portion 109B of the gate electrode 109. This difference will be described in detail in a method for manufacturing the DRAM 201 (see below).

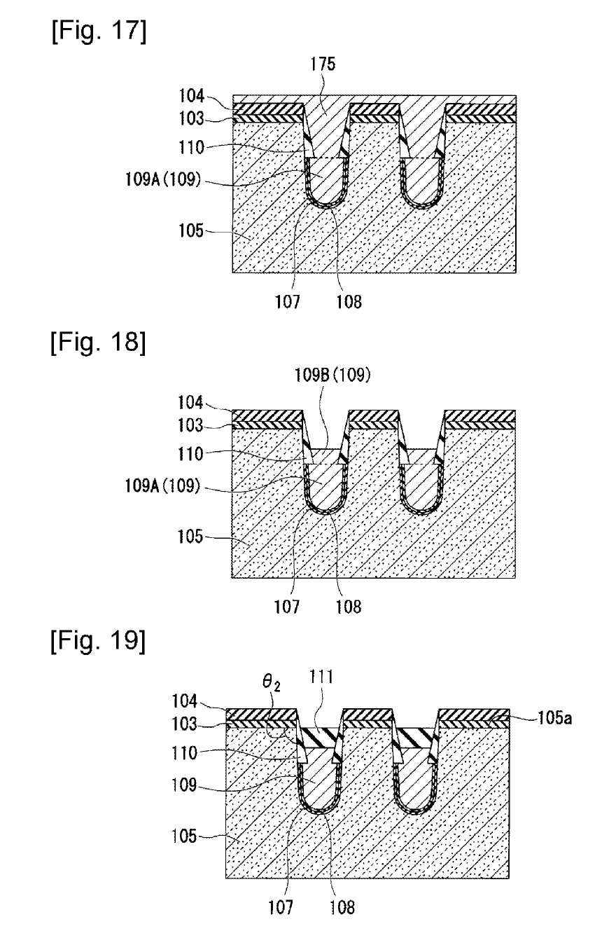

The method for manufacturing the DRAM 201 will be described below with the aid of FIG. 17 to FIG. 19. Refer to the description given in relation to the first mode of embodiment for the steps which are duplicated from the method for producing the DRAM 101 according to the first mode of embodiment, as these steps will not be described here.

The same steps as in the method for manufacturing the DRAM 101, from preparation of the semiconductor substrate 105 until the side wall insulating film formation step, are carried out first of all.

### [Gate Electrode Formation Second Step]

A tungsten layer 175 is formed using CVD in such a way as to fill the mortar-shaped space enclosed by the side wall insulating film 110 on the lower portion 109A of the gate electrode 109 and in such a way as to extend over the silicon nitride film 104, as shown in FIG. 17. The thickness of the tungsten layer 175 may be set at 50 nm, for example, at the thinnest portion on the silicon nitride film 104.

The upper part of the tungsten layer 175 is then etched back in such a way as to remain at a predetermined thickness on the bottom part of a mortar-shaped space enclosed by the lower portion 109A and the upper portion 109B of the gate electrode 109. As a result, the gate electrode 109 is formed by joining of the lower portion 109A which is enclosed by the laminated film comprising the gate insulating film 107 and the inner surface layer 108, except on the upper surface thereof, and the upper portion 109B which is enclosed at the side surface by a bottom part of the side wall insulating film 110, as shown in FIG. 18. The thickness of the upper portion 109B is preferably set in accordance with the thickness of the lower portion 109A and takes account of the overall thickness of the gate electrode 109.

### [Embedded Insulating Film Formation Step]

A mortar-shaped internal space in the trench 106 enclosed by an exposed portion of the upper portion 109B of the gate electrode 109 and the side wall insulating film 110 is then filled with the embedded insulating film 111 comprising a silicon dioxide film using an HDP method. Here, the interior angle θ₂ formed by the surface 105a of the semiconductor substrate 105 in the region of the upper end of the trench 106 and the inner wall of the side wall insulating film 110 is an obtuse angle, and therefore there is no risk of the upper end of the side wall insulating film 110 being removed by the sputtering effect produced by the HDP method. Furthermore, it is possible to improve the ease of embedding the embedded insulating film 111 in the mortar-shaped internal space in the trench 106 enclosed by the exposed portion of the upper portion 109B of the gate electrode 109 and the side wall insulating film 110. It should be noted that the height of the upper surface of the embedded insulating film 111 can be aligned with the height of the surface 105a of the semiconductor substrate 105 using etch-back or the like, in the same way as in the DRAM 101.

Following this, the same steps as in the method for manufacturing the DRAM 101 are performed for the bit line formation step and subsequent steps. The DRAM 201 is completed as a result.

The DRAM 201 and method for manufacturing same according to this mode of embodiment achieve the same advantages as the DRAM 101 and method for manufacturing same. It is therefore possible to reliably maintain the insulating properties of the gate electrodes 109 of the DRAM 201 and to avoid short circuiting between the gate electrodes 109 and the capacitance contact plugs 119 or bit lines 115. Furthermore, a field limiting effect can be produced in the DRAM 201 by means of the side wall insulating film 110, and the refresh characteristics can be improved. In addition, the gate electrodes 109 comprise the lower portion 109A and the upper portion 109B, and it is possible to reduce the electrical resistance without increasing the word line capacitance of the DRAM 201.

Preferred modes of embodiment of the present invention have been described above but the present invention is not limited to these specific modes of embodiment and a number of variations and modifications may be made within the essential scope of the present invention as set forth in the claims.

### KEY TO SYMBOLS

65 . . . Trench groove; 101, 201 . . . DRAM (semiconductor device); 103 . . . Silicon dioxide film; 104, 180 . . . Silicon nitride film; 50, 105 . . . Semiconductor substrate; 105a . . . Surface; 106 . . . Trench; 107 . . . Gate insulating film; 108 . . . Inner surface layer; 109 . . . Gate electrode; 109A . . . Lower portion; 109B . . . Upper portion; 110 . . . Side wall insulating film; 72, 111 . . . Embedded insulating film; 113, 158 . . . Element isolation region; 115 . . . Bit line; 118 . . . Capacitance contact pad: 121 . . . Stopper film; 130, 140 . . . Bottom conductive film; 131, 142 . . . Metallic film; 133, 137 . . . Insulating film; 141 . . . Silicide layer; 143, 146, 151, 154 . . . Interlayer insulating film; 147 . . . Capacitor; 148 . . . Lower electrode; 149 . . . Capacitance insulating film; 150 . . . Upper electrode; 152 . . . Upper metal wiring; 71, 161 . . . Liner film; 170, 175 . . . Tungsten layer; 172 . . . Antireflection film; 176 . . . Bit line opening; 187 . . . Capacitance contact opening; K . . . Active region; θ₁, θ₂ . . . Interior angle

1. A semiconductor device comprising:
a trench formed in one surface of a semiconductor substrate;
a gate electrode formed in a lower part of the trench with a gate insulating film interposed;
a side wall insulating film comprising a nitride film formed on an inner wall of the trench on the gate electrode; and
an embedded insulating film which is formed within the trench enclosed by the side wall insulating film on the gate electrode,
wherein the side wall insulating film has a shape which increases in width toward a bottom part of the trench.

2. The semiconductor device as claimed in claim 1, wherein the embedded insulating film comprises an oxide film formed by means of a high-density plasma method.

3. The semiconductor device as claimed in claim 1, wherein the gate electrode extends into the trench enclosed by a bottom part of the side wall insulating film.

4. The semiconductor device as claimed in claim 1, comprising:
a contact plug which is formed in such a way as to connect to one side of the semiconductor substrate adjacent to the trench; and
a bit line which is formed in such a way as to connect to the other side of the semiconductor substrate.

5. The semiconductor device as claimed in claim 4, comprising a capacitor which is formed in such a way as to connect to the contact plug.

6. A method for manufacturing a semiconductor device, comprising:
forming a trench in one surface of a semiconductor substrate;
forming a gate insulating film at a lower part of an inner wall of the trench;
forming a gate electrode at a lower part of the trench with the gate insulating film interposed;
forming a side wall insulating film comprising a nitride film which increases in width toward a bottom part of the trench on an inner wall of the trench on a buried word line; and
forming an embedded insulating film within the trench enclosed by the side wall insulating film on the gate electrode.

7. The method for manufacturing a semiconductor device as claimed in claim 6, wherein forming the embedded insulating film comprises forming an oxide film within the trench enclosed by the side wall insulating film on the gate electrode, using a high-density plasma method.

8. The method for manufacturing a semiconductor device as claimed in claim 6, wherein forming the gate electrode comprises:
forming a lower portion of the gate electrode in a lower part of the trench with the gate insulating film interposed; and
forming an upper portion of the gate electrode which is joined to the lower portion within the trench enclosed by a bottom part of the side wall insulating film.

9. The method for manufacturing a semiconductor device as claimed in claim 6, comprising, after forming the embedded insulating film:
forming a contact plug adjoining a surface on one side of the semiconductor substrate adjacent to the trench and the upper surface of the embedded insulating film; and
forming a bit line adjoining a surface on the other side of the semiconductor substrate adjacent to the trench and the upper surface of the embedded insulating film.

10. The method for manufacturing a semiconductor device as claimed in claim 9, comprising forming a capacitor connected to the contact plug.
